(19) United States
(12) Patent Application Publication
(10) Pub. No.: US 2025/0316488 A1
(43) Pub. Date: Oct. 9, 2025

(54) SEMICONDUCTOR DEVICE MANUFACTURING METHOD

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Masaaki OGAWA, Hakusan Ishikawa (JP)

(21) Appl. No.: 18/785,403

(22) Filed: Jul. 26, 2024

(30) Foreign Application Priority Data
Apr. 5, 2024 (JP) 2024-061713

(51) Int. Cl. H01L 21/304; H01L 21/02; H01L 21/306

(52) U.S. Cl. CPC H01L 21/3043; H01L 21/02118; H01L 21/02164; H01L 21/0217; H01L 21/022; H01L 21/30608

(57) ABSTRACT

A semiconductor device manufacturing method according to the present embodiment includes forming a recess on a second surface of a wafer, the wafer including a first surface on which a semiconductor element is provided and the second surface on a side opposite to the first surface, so as to form, on the second surface, a thin plate portion and an annular protrusion portion that surrounds the thin plate portion. The present manufacturing method includes forming a first film on the second surface. The present manufacturing method includes removing a part of the first film such that at least a part of the first film remains in a boundary portion between the thin plate portion and the annular protrusion portion.

### CROSS REFERENCE TO RELATED APPLICATIONS

This application is based upon and claims the benefit of priority from the prior Japanese Patent Application No. 2024-061713, filed on Apr. 5, 2024, the entire contents of which are incorporated herein by reference.

### FIELD

The embodiments of the present invention relate to a semiconductor device manufacturing method.

### BACKGROUND

Manufacturing processes for a semiconductor device (such as an IGBT (Insulated Gate Bipolar Transistor) and an LV-MOS (Low-Voltage Metal-Oxide-Semiconductor)) include a TAIKO (registered trademark) process in which the thickness (for example, Si thickness) of a wafer is thinned such that an inner side of the wafer is grinded while maintaining an annular thick film portion (rim portion) on an outer circumferential portion of the wafer. In recent years, the necessity for further thinning of the wafer thickness has been increasing due to a demand for improved device characteristics. However, as the wafer thickness is made thinner, the load of the stress exerted on a boundary portion between the rim portion and a membrane portion (thin film portion formed by grinding) increases in some cases. In particular, after forming a back surface electrode, performing plating on a surface electrode, or the like, a crack is generated starting from the boundary portion, which could result in defects such as breakage of the wafer in some cases.

### BRIEF DESCRIPTION OF THE DRAWINGS

FIG. 1A is a cross-sectional view showing an example of a semiconductor device manufacturing method according to a first embodiment;

FIG. 1B is a cross-sectional view showing the example of the semiconductor device manufacturing method subsequent to FIG. 1A;

FIG. 1C is a cross-sectional view showing the example of the semiconductor device manufacturing method subsequent to FIG. 1B;

FIG. 1D is a cross-sectional view showing the example of the semiconductor device manufacturing method subsequent to FIG. 1C;

FIG. 1E is a cross-sectional view showing the example of the semiconductor device manufacturing method subsequent to FIG. 1D;

FIG. 2 is a top view showing an example of the configuration of a semiconductor wafer according to the first embodiment;

FIG. 3 is a cross-sectional view showing the example of the configuration of the semiconductor wafer according to the first embodiment;

FIG. 4A is a chart showing an example of stress simulation according to a comparative example;

FIG. 4B is a chart showing an example of stress simulation according to the first embodiment;

FIG. 5A is a cross-sectional view showing an example of a semiconductor device manufacturing method according to a second embodiment;

FIG. 5B is a cross-sectional view showing the example of the semiconductor device manufacturing method subsequent to FIG. 5A;

FIG. 5C is a cross-sectional view showing the example of the semiconductor device manufacturing method subsequent to FIG. 5B;

FIG. 5D is a cross-sectional view showing the example of the semiconductor device manufacturing method subsequent to FIG. 5C;

FIG. 6 is a cross-sectional view showing an example of the configuration of the semiconductor wafer according to the second embodiment;

FIG. 7A is a cross-sectional view showing an example of a semiconductor device manufacturing method according to a third embodiment;

FIG. 7B is a cross-sectional view showing the example of the semiconductor device manufacturing method subsequent to FIG. 7A;

FIG. 7C is a cross-sectional view showing the example of the semiconductor device manufacturing method subsequent to FIG. 7B;

FIG. 8 is a cross-sectional view showing an example of the configuration of the semiconductor wafer according to the third embodiment;

FIG. 9A is a cross-sectional view showing an example of a semiconductor device manufacturing method according to a fourth embodiment;

FIG. 9B is a cross-sectional view showing the example of the semiconductor device manufacturing method subsequent to FIG. 9A;

FIG. 9C is a cross-sectional view showing the example of the semiconductor device manufacturing method subsequent to FIG. 9B;

FIG. 9D is a cross-sectional view showing the example of the semiconductor device manufacturing method subsequent to FIG. 9C;

FIG. 9E is a cross-sectional view showing the example of the semiconductor device manufacturing method subsequent to FIG. 9D;

FIG. 10 is a top view showing an example of the configuration of the semiconductor wafer according to the fourth embodiment;

FIG. 11 is a cross-sectional view showing the example of the configuration of the semiconductor wafer according to the fourth embodiment; and

FIG. 12 is a chart showing an example of stress simulation according to the fourth embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device manufacturing method according to the present embodiment includes forming a recess on a second surface of a wafer, the wafer including a first surface on which a semiconductor element is provided and the second surface on a side opposite to the first surface, so as to form, on the second surface, a thin plate portion and an annular protrusion portion that surrounds the thin plate portion. The present manufacturing method includes forming a first film on the second surface. The present manufacturing method includes removing a part of the first film such that at least a part of the first film remains in a boundary portion between the thin plate portion and the annular protrusion portion.

### First Embodiment

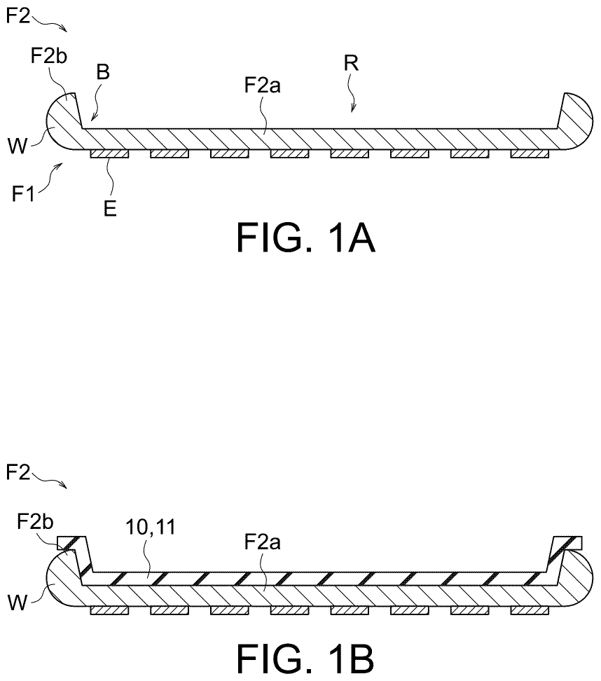

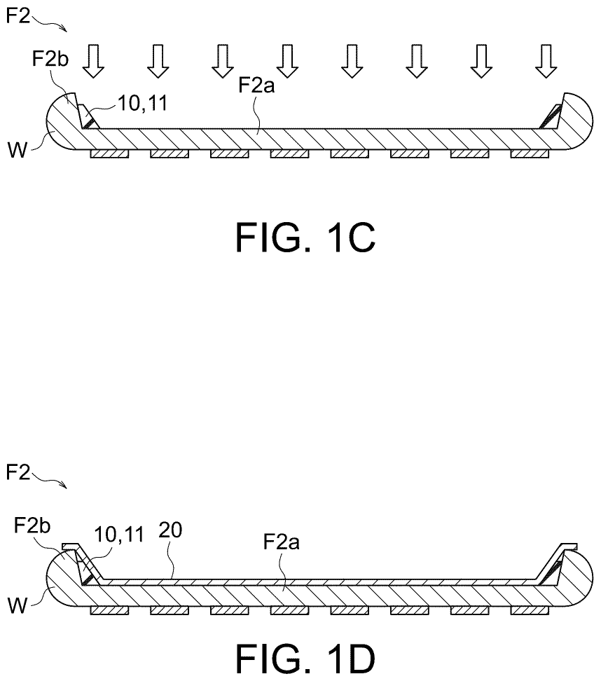

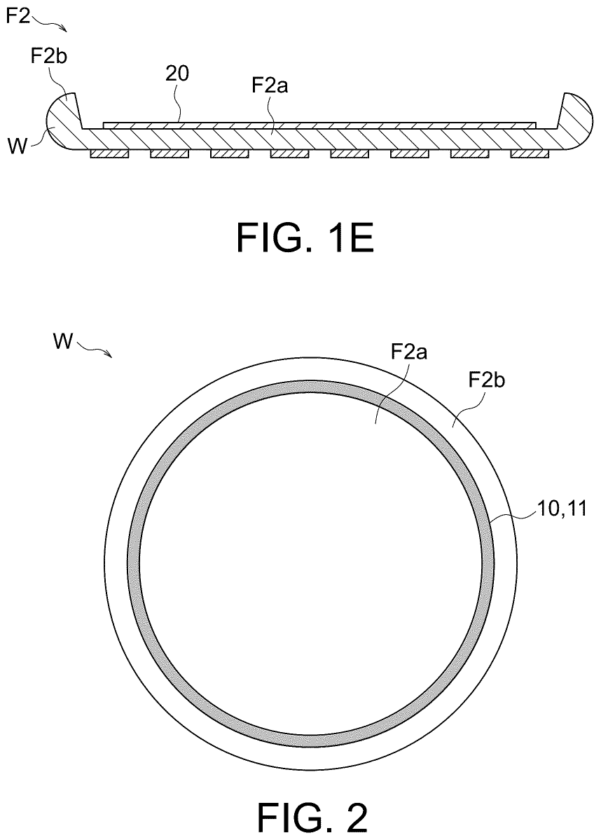

FIG. 1A to FIG. 1E are cross-sectional views showing an example of a semiconductor device manufacturing method according to a first embodiment.

A semiconductor wafer W includes a first surface F1 and a second surface F2 on a side opposite to the first surface F1. The first surface F1 is provided with a semiconductor element E. Note that prior to the process shown in FIG. 1A, a protection film (not shown) for protecting the semiconductor element E is formed on the first surface F1.

First, as shown in FIG. 1A, a recess R is formed on the second surface F2 of the semiconductor wafer W so that a thin plate portion F2a (membrane portion) and an annular protrusion portion F2b (rim portion) are formed on the second surface F2. The rim portion F2b is formed so as to surround the membrane portion F2a in an outer circumferential portion of the semiconductor wafer W. The recess R is formed in a center region of the second surface F2 that overlaps at least the semiconductor element E as viewed in a direction substantially perpendicular to the semiconductor wafer W. The recess R is, for example, substantially circular as viewed from the second surface F2 side (see FIG. 2).

Next, as shown in FIG. 1B, a first film 10 is formed on the second surface F2. More specifically, an inorganic insulating film 11 is formed on the second surface F2. In other words, the first film 10 according to the first embodiment is a single layer film of the inorganic insulating film 11. The inorganic insulating film 11 is, for example, a silicon oxide film (SiO₂), but may be a silicon nitride film (SIN). The silicon oxide film is formed by, for example, low-temperature CVD (Chemical Vapor Deposition), sputtering (PVD (Physical Vapor Deposition)), or coating.

Next, as shown in FIG. 1C, a part of the first film 10 is removed such that at least a part of the first film 10 remains in a boundary portion B between the membrane portion F2a and the rim portion F2b. More specifically, the first film 10 is removed by anisotropic etching until the membrane portion F2a is exposed. In other words, etch back is performed by entire surface RIE (Reactive Ion Etching).

FIG. 2 is a top view showing an example of the configuration of the semiconductor wafer W according to the first embodiment. FIG. 2 is a view of the semiconductor wafer W in the process shown in FIG. 1C as viewed from the second surface F2 side.

The first film 10 is provided in the boundary portion B between the rim portion F2b and the membrane portion F2a as viewed from the second surface F2 side. The first film 10 functions as a reinforcing member. This can suppress generation of defects such as breakage or chipping of the semiconductor wafer W in the manufacturing process.

Next, as shown in FIG. 1D, a metal film 20 is formed on the first film 10 remaining in the boundary portion B and the second surface F2. The metal film 20 is formed by, for example, sputtering.

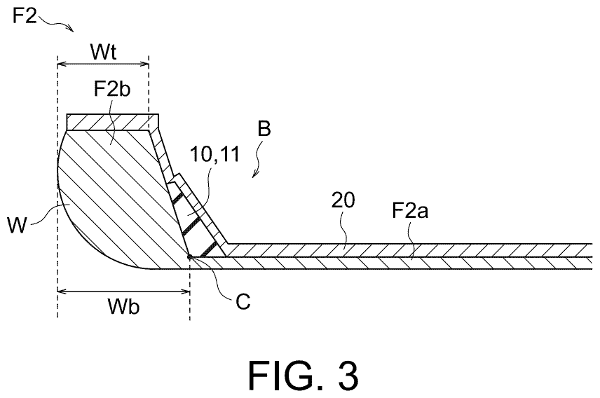

FIG. 3 is a cross-sectional view showing the example of the configuration of the semiconductor wafer W according to the first embodiment. FIG. 3 is an enlarged cross-sectional view of the semiconductor wafer W in the vicinity of the boundary portion B shown in FIG. 1D.

A corner portion C is a corner portion where a surface of the membrane portion F2a and an inner side surface of the rim portion F2b intersect with each other and is included in the boundary portion B.

Next, as shown in FIG. 1E, the first film 10 is removed. By doing this, the metal film 20 on the first film 10 is also removed (lift-off). A silicon oxide film as the first film 10 (inorganic insulating film 11) is removed by, for example, HF wet etching. For example, a chemical solution enters from a gap (not shown in FIG. 3) of the metal film 20, so that the first film 10 is removed.

Next, the rim portion F2b is removed from the semiconductor wafer W. The rim portion F2b is removed by cutting, into a ring-shape, a region where the first film 10 and the metal film 20 on the first film 10 are removed. Therefore, a load exerted on the semiconductor wafer W due to cutting of the metal film 20 can be mitigated. Next, the semiconductor wafer W is singulated into a plurality of chips by dicing. The metal film 20 functions as a back surface electrode. In this case, the semiconductor device is, for example, a device that causes current to flow in an up-down direction on the sheet of FIG. 3.

Note that the process shown in FIG. 1E may be omitted. In this case, the rim portion F2b is removed by cutting an inner side of the first film 10 into a ring-shape.

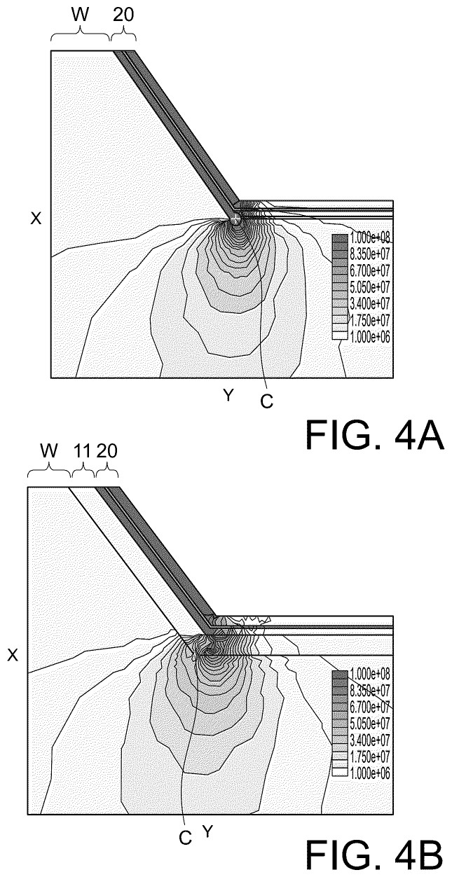

Next, results of stress simulation will be described. The stress described below is a stress exerted on the corner portion C of FIG. 3, FIG. 4A, and FIG. 4B.

FIG. 4A is a chart showing an example of stress simulation according to a comparative example. FIG. 4B is a chart showing an example of stress simulation according to the first embodiment. The stress (Pa) distribution in the vicinity of the corner portion C is denoted by contour lines. The longitudinal axis of a graph represents an X-coordinate and the lateral axis of the graph represents a Y-coordinate.

FIG. 4A shows a case in which the first film 10 is not formed (comparative example). FIG. 4B shows a case in which the inorganic insulating film 11 (TEOS (Tetra-ethoxy silane) film) having 2 μm is formed (first embodiment). Note that the inorganic insulating film 11 is formed in a range of ±50 μm from the corner portion C in a Y-axis direction of FIG. 4A and FIG. 4B. Further, the metal film 20 is a stacked film including an aluminum (Al) film, a titanium (Ti) film, and a nickel (Ni) film.

In FIG. 4A, the position with a higher stress is closer to the corner portion C. In FIG. 4B, as compared to FIG. 4A, the position with a higher stress is farther from the corner portion C.

In FIG. 4A, a stress σ_{XX} in an X-direction exerted on an X-surface is 1.787×10⁸ (Pa), a stress σ_{XY} in a Y-direction exerted on a Y-surface is 1.318×10⁸ (Pa), and a stress σ_{YY} in the Y-direction exerted on the X-surface is −7.813×10⁶ (Pa). In FIG. 4B, the stress σ_{XX} in the X-direction exerted on the X-surface is 1.117×10⁷ (Pa), the stress σ_{YY} in the Y-direction exerted on the Y-surface is −2.270×10⁷ (Pa), and the stress σ_{XY} in the Y-direction exerted on the X-surface is −1.639×10⁷ (Pa). Accordingly, as compared to the comparative example, the stress (stress σ_{XX}) can be reduced by one digit, with the inorganic insulating film 11.

As described above, according to the first embodiment, the recess R is formed on the second surface F2 of the semiconductor wafer W so that the membrane portion F2a and the rim portion F2b are formed on the second surface F2. Further, the first film 10 is formed on the second surface F2. Furthermore, a part of the first film 10 is removed such that at least a part of the first film 10 remains in the boundary portion B. In this manner, the boundary portion B between the rim portion F2b and the membrane portion F2a can be reinforced. As a result, an inner side of the rim portion F2b is reinforced and generation of defects such as breakage or chipping of the semiconductor wafer W in the manufacturing process can be suppressed. Accordingly, the yield lowered due to wafer breakage can be improved.

Note that as shown in FIG. 3, the inner side surface of the rim portion F2b has a slope shape. However, also for the rim portion F2b in other shapes such as those in which the inner side surface of the rim portion does not have a slope shape, the first embodiment is also applicable.

As a method for reinforcing the boundary portion B between the rim portion F2b and the membrane portion F2a, it is conceivable that the rim portion F2b has a sloped shape and further, the slope angle is formed gradual. However, when a rim top width Wt does not change, since the slope angle is gradual, a rim bottom width Wb increases to thus increase an ineffective region in the outer circumferential portion of the wafer, thereby reducing the chip gross (chip yield per wafer). Meanwhile, when the chip gross is maintained without changing the rim bottom width Wb, the rim top width Wt is narrowed and the rigidity of the semiconductor wafer W deteriorates, and in a manufacturing device that clamps the outer circumferential portion of the wafer for transfer and processing, breakage during transfer is concerned.

By contrast, in the first embodiment, the first film 10 functioning as a reinforcing member is formed, without changing the slope angle, the rim top width Wt, and the rim bottom width Wb. Thus, the boundary portion B between the rim portion F2b and the membrane portion F2a can be reinforced without impairing the rigidity of the semiconductor wafer W while maintaining the chip gross.

### Second Embodiment

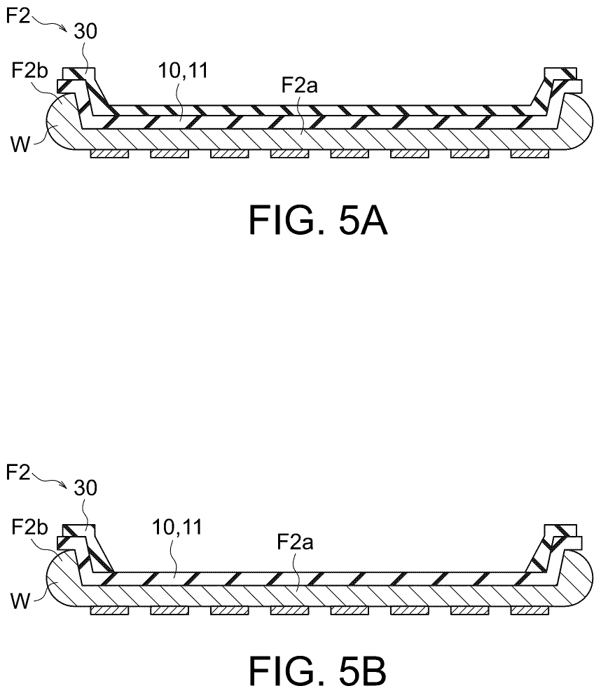

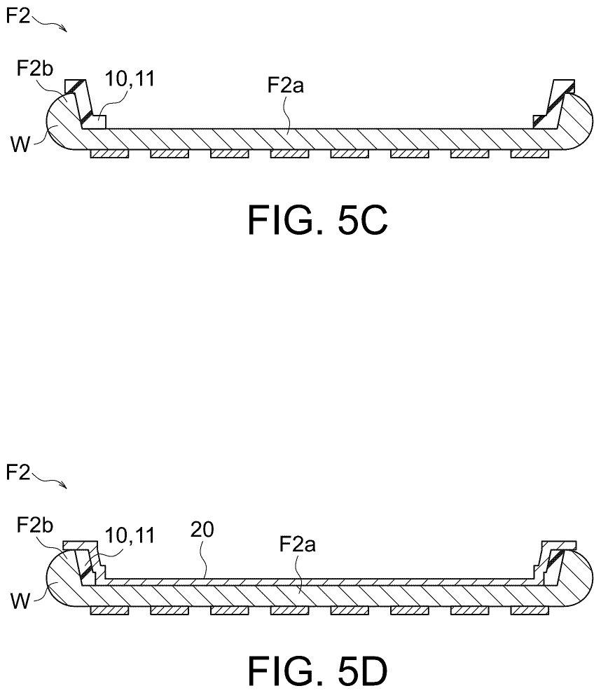

FIG. 5A to FIG. 5D are cross-sectional views showing an example of a semiconductor device manufacturing method according to a second embodiment. The process shown in FIG. 5A is performed after the same processes as those of FIG. 1A and FIG. 1B.

The second embodiment differs from the first embodiment in that a part of the first film 10 remaining in the boundary portion B is removed by resist patterning and wet etching, in place of etch back by entire surface RIE.

After forming the inorganic insulating film 11 on the second surface F2 (see FIG. 1B), a resist 30 is coated on the inorganic insulating film 11 as shown in FIG. 5A.

Next, as shown in FIG. 5B, the resist 30 is patterned so as to cover the boundary portion B between the rim portion F2b and the membrane portion F2a. In other words, a pattern corresponding to the boundary portion B is formed in the resist 30.

Next, as shown in FIG. 5C, the inorganic insulating film 11 is etched to strip off the resist 30. In other words, the inorganic insulating film 11 is removed using, as a mask, the resist 30 with the pattern shown in 5B. The etching of the silicon oxide film as the inorganic insulating film 11 is, for example, HF wet etching.

Next, as shown in FIG. 5D, the metal film 20 is formed on the remaining first film 10 and the second surface F2. The process shown in FIG. 5D is the same as the process shown in FIG. 1D.

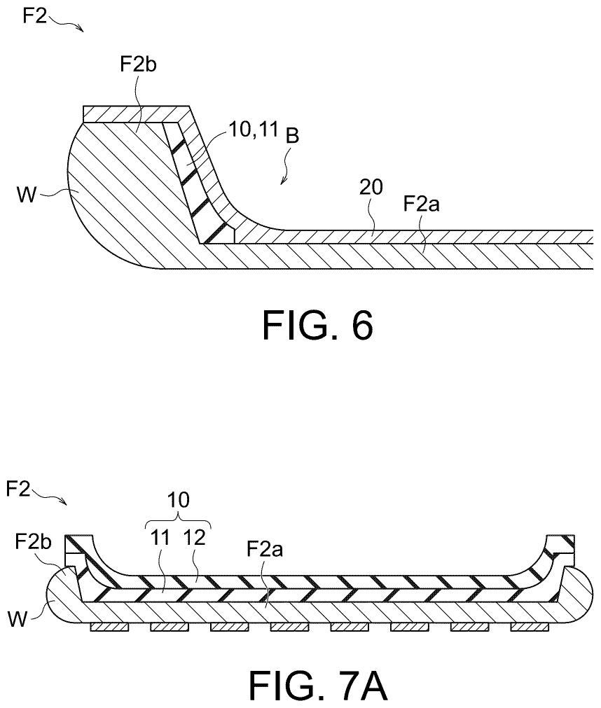

FIG. 6 is a cross-sectional view showing an example of the configuration of the semiconductor wafer W according to the second embodiment. FIG. 6 is an enlarged cross-sectional view of the semiconductor wafer W in the vicinity of the boundary portion B shown in FIG. 5D.

Subsequently, the same processes as those after the process shown in FIG. 1E are performed.

As in the second embodiment, the method for removing a part of the first film 10 may be changed. The semiconductor device manufacturing method according to the second embodiment can obtain the same advantageous effects as those of the first embodiment.

### Third Embodiment

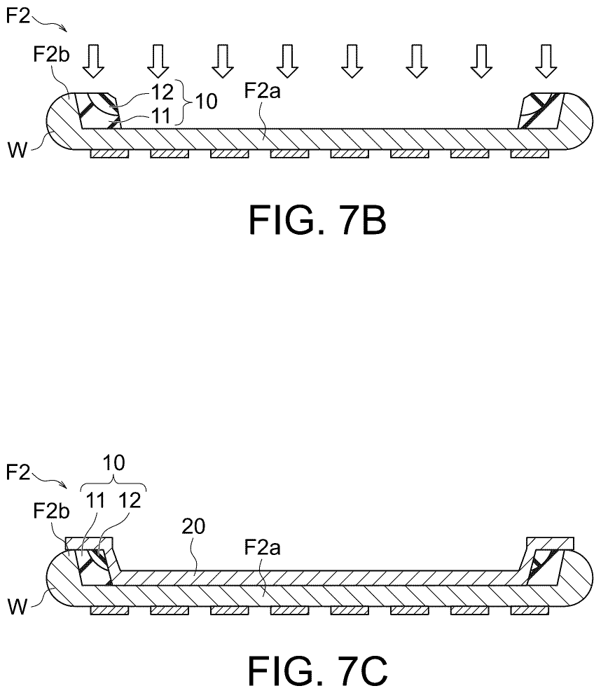

FIG. 7A to FIG. 7C are cross-sectional views showing an example of a semiconductor device manufacturing method according to a third embodiment. The process shown in FIG. 7A is performed after the same processes as those of FIG. 1A and FIG. 1B.

The third embodiment differs from the first embodiment in that the first film 10 is a stacked film.

After forming the inorganic insulating film 11 on the second surface F2 (see FIG. 1B), an inorganic insulating film 12 is formed on the inorganic insulating film 11 as shown in FIG. 7. The first film 10 according to the third embodiment is a stacked film including a plurality of inorganic insulating films 11, 12. In the third embodiment, for example, the silicon oxide film as the inorganic insulating film 11 is formed by coating and the silicon oxide film as the inorganic insulating film 12 is formed by, for example, coating or CVD.

The film thickness of the silicon oxide film that can be formed at one time is, for example, several μm. If the stress exerted on the boundary portion B cannot be mitigated to a level of a desired strength, reinforcement is possible by stacking many layers to thicken the first film 10.

Note that the stacked film is not limited to a film with two layers, and may be a film with three or more layers. Further, the materials of the inorganic insulating films 11, 12 and films further stacked may differ from one another.

Next, as shown in FIG. 7B, a part of the first film 10 is removed such that at least a part of the first film 10 remains in the boundary portion B. The process shown in FIG. 7B is the same as the process shown in FIG. 1C.

Next, as shown in FIG. 7C, the metal film 20 is formed on the remaining first film 10 and the second surface F2. The process shown in FIG. 7C is the same as the process shown in FIG. 1D.

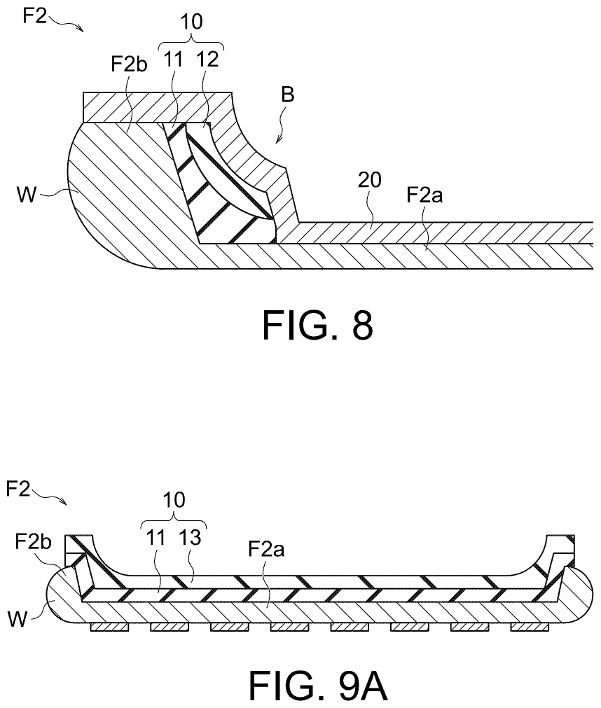

FIG. 8 is a cross-sectional view showing an example of the configuration of the semiconductor wafer W according to the third embodiment. FIG. 8 is enlarged cross-sectional view of the semiconductor wafer W in the vicinity of the boundary portion B shown in FIG. 7C.

Subsequently, the same processes as those after the process shown in FIG. 1E are performed.

As in the third embodiment, the first film 10 may be a stacked film. The semiconductor device manufacturing method according to the third embodiment can obtain the same advantageous effects as those of the first embodiment. Further, the second embodiment may be combined with the semiconductor device manufacturing method according to the third embodiment.

### Fourth Embodiment

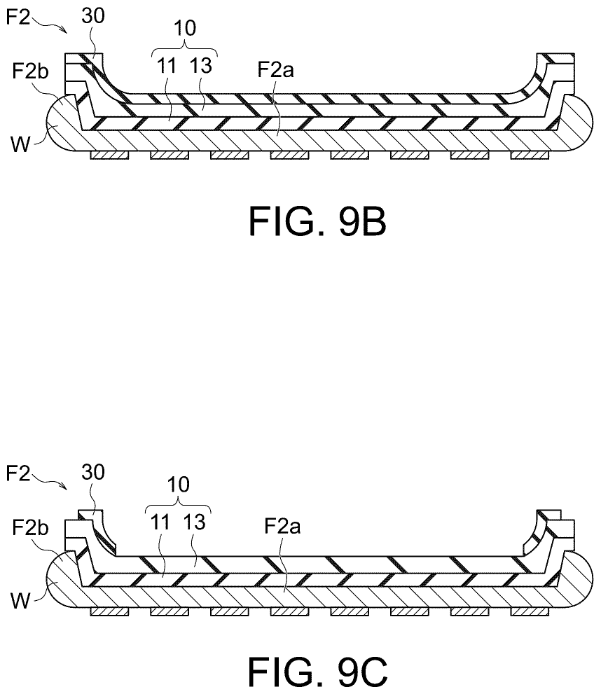

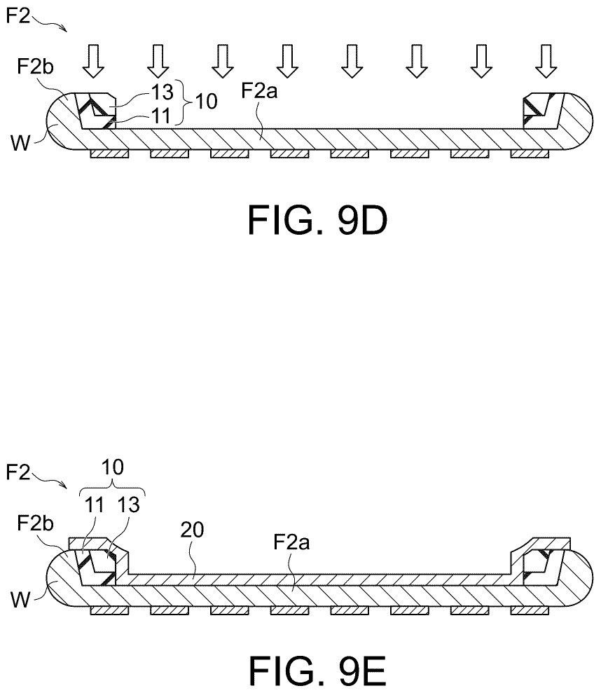

FIG. 9A to FIG. 9E are cross-sectional views showing an example of a semiconductor device manufacturing method according to a fourth embodiment. The process shown in FIG. 9A is performed after the same processes as those of FIG. 1A and FIG. 1B. Note that in the fourth embodiment, resist patterning and wet etching are performed as in the second embodiment. However, etch back by entire surface RIE may be performed.

The fourth embodiment differs from the third embodiment in that the first film 10 is a stacked film including an organic insulating film 13.

After forming the inorganic insulating film 11 on the second surface F2 (see FIG. 1B), the organic insulating film 13 is formed on the inorganic insulating film 11 as shown in FIG. 9A. The first film according to the fourth embodiment is a stacked film including the inorganic insulating film 11 and the organic insulating film 13. The organic insulating film 13 is, for example, a polyimide film. Note that the stacked film may be a stacked film of the inorganic insulating films 11, the organic insulating films 13, or a combination of these films.

Next, as shown in FIG. 9B, the resist 30 is coated on the organic insulating film 13. The process shown in FIG. 9B is the same as the process shown in FIG. 5A.

Next, as shown in FIG. 9C, the resist 30 is patterned so as to cover the boundary portion B between the rim portion F2b and the membrane portion F2a. The process shown in FIG. 9C is the same as the process shown in FIG. 5B.

Next, as shown in FIG. 9D, patterning of the organic insulating film 13 and wet etching of the inorganic insulating film 11 are performed. The etching of the silicon oxide film as the inorganic insulating film 11 is, for example, HF wet etching.

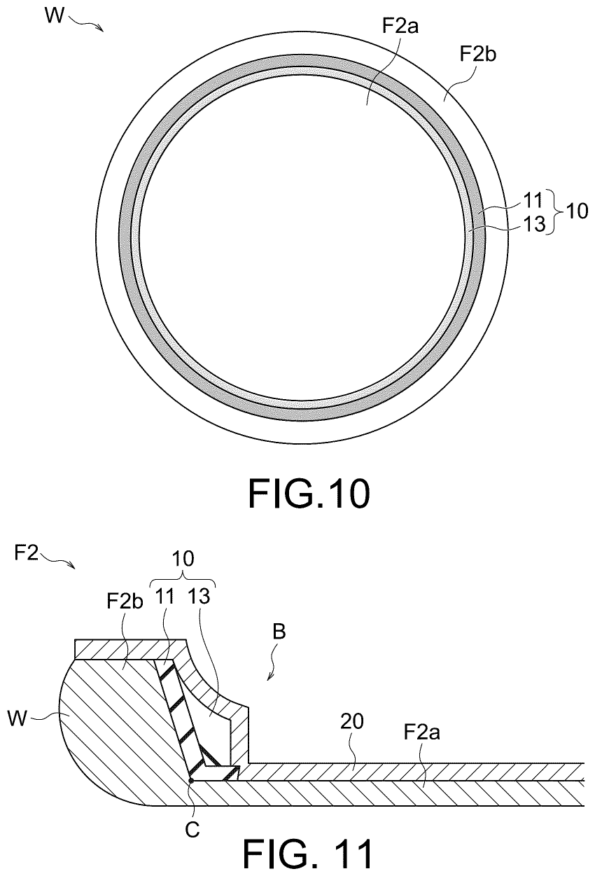

FIG. 10 is a top view showing an example of the configuration of the semiconductor wafer W according to the fourth embodiment. FIG. 10 is a view of the semiconductor wafer W in the process shown in FIG. 9D as viewed from the second surface F2 side.

The first film 10 including the inorganic insulating film 11 and the organic insulating film 13 is provided in the boundary portion B between the rim portion F2b and the membrane portion F2a as viewed in a direction substantially perpendicular to the semiconductor wafer W.

Next, as shown in FIG. 9E, the metal film 20 is formed on the remaining first film 10 and the second surface F2. The process shown in FIG. 9E is the same as the process shown in FIG. 1D.

FIG. 11 is a cross-sectional view showing an example of the configuration of the semiconductor wafer W according to the fourth embodiment. FIG. 11 is an enlarged cross-sectional view of the semiconductor wafer W in the vicinity of the boundary portion B shown in FIG. 9E.

Subsequently, the same processes as those after the process shown in FIG. 1E are performed.

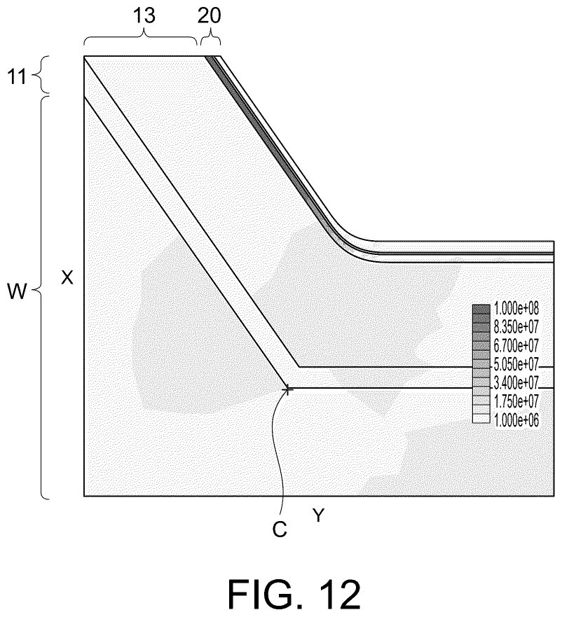

Next, results of stress simulation will be described. The stress described below is a stress exerted on the corner portion C of FIG. 11 and FIG. 12.

FIG. 12 is a chart showing an example of stress simulation according to the fourth embodiment. The stress (Pa) distribution in the vicinity of the corner portion C is denoted by contour lines. The longitudinal axis of a graph represents an X-coordinate and the lateral axis of the graph represents a Y-coordinate.

FIG. 12 shows a case in which the inorganic insulating film 11 having 2 μm and the organic insulating film 13 having 10 μm are formed. Note that the inorganic insulating film 11 and the organic insulating film 13 are formed in a range of 50 μm from the corner portion C in a Y-axis direction of FIG. 12. Further, the metal film 20 is a stacked film including an aluminum (Al) film, a titanium (Ti) film, and a nickel (Ni) film.

In FIG. 12, the stress σ_{XX} in the X-direction exerted on the X-surface is −1.003×10⁶ (Pa), the stress σ_{YY} in the Y-direction exerted on the Y-surface is 1.296×10⁷ (Pa), the stress σ_{XY} in the Y-direction exerted on the X-surface is 1.2196×10⁷ (Pa). Accordingly, as compared to the first embodiment, the stress (stress σ_{XX}) can be reduced by one digit, with the organic insulating film 13.

Note that when the organic insulating film 13 has photosensitivity, the organic insulating film 13 may be patterned without using the resist 30.

As in the fourth embodiment, the first film 10 may be a stacked film including the organic insulating film 13. The semiconductor device manufacturing method according to the fourth embodiment can obtain the same advantageous effects as those of the third embodiment.

While certain embodiments have been described, these embodiments have been presented by way of example only, and are not intended to limit the scope of the inventions. Indeed, the novel 5 methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device manufacturing method, comprising:
forming a recess on a second surface of a wafer, the wafer including a first surface on which a semiconductor element is provided and the second surface on a side opposite to the first surface, so as to form, on the second surface, a thin plate portion and an annular protrusion portion that surrounds the thin plate portion;
forming a first film on the second surface; and
removing a part of the first film such that at least a part of the first film remains in a boundary portion between the thin plate portion and the annular protrusion portion.

2. The semiconductor device manufacturing method according to claim 1, wherein the removing the part of the first film comprises removing the first film by anisotropic etching until the thin plate portion is exposed.

3. The semiconductor device manufacturing method according to claim 1, wherein the removing the part of the first film comprises:
forming a mask member on the first film;
forming, in the mask member, a pattern corresponding to the boundary portion; and
removing the first film using the mask member having the pattern as a mask.

4. The semiconductor device manufacturing method according to claim 1, wherein the first film is a single layer film.

5. The semiconductor device manufacturing method according to claim 4, wherein the single layer film is an inorganic insulating film or an organic insulating film.

6. The semiconductor device manufacturing method according to claim 5, wherein
the inorganic insulating film is at least one of a silicon oxide film or a silicon nitride film, and
the organic insulating film is a polyimide film.

7. The semiconductor device manufacturing method according to claim 1, wherein the first film is a stacked film.

8. The semiconductor device manufacturing method according to claim 7, wherein the stacked film is a stacked film of an inorganic insulating film, an organic insulating film, or a combination of the inorganic insulating film and the organic insulating film.

9. The semiconductor device manufacturing method according to claim 8, wherein
the inorganic insulating film is at least one of a silicon oxide film or a silicon nitride film, and
the organic insulating film is a polyimide film.

10. The semiconductor device manufacturing method according to claim 1, further comprising;
after removing the part of the first film,
forming a metal film on the first film remaining in the boundary portion and the second surface,
removing the first film,
removing the annular protrusion portion from the wafer, and singulating the wafer into a plurality of chips.

11. The semiconductor device manufacturing method according to claim 1, wherein the boundary portion is a corner portion where a surface of the thin plate portion and an inner side surface of the annular protrusion portion intersect with each other.

12. The semiconductor device manufacturing method according to claim 1, wherein the forming the recess comprises grinding a center portion of the second surface that overlaps the semiconductor element as viewed in a direction substantially perpendicular to the wafer.

13. The semiconductor device manufacturing method according to claim 2, wherein the first film is a single layer film.

14. The semiconductor device manufacturing method according to claim 3, wherein the first film is a single layer film.

15. The semiconductor device manufacturing method according to claim 2, wherein the first film is a stacked film.

16. The semiconductor device manufacturing method according to claim 3, wherein the first film is a stacked film.

17. The semiconductor device manufacturing method according to claim 2, wherein the boundary portion is a corner portion where a surface of the thin plate portion and an inner side surface of the annular protrusion portion intersect with each other.

18. The semiconductor device manufacturing method according to claim 3, wherein the boundary portion is a corner portion where a surface of the thin plate portion and an inner side surface of the annular protrusion portion intersect with each other.

19. The semiconductor device manufacturing method according to claim 2, wherein the forming the recess comprises grinding a center portion of the second surface that overlaps the semiconductor element as viewed in a direction substantially perpendicular to the wafer.

20. The semiconductor device manufacturing method according to claim 3, wherein the forming the recess comprises grinding a center portion of the second surface that overlaps the semiconductor element as viewed in a direction substantially perpendicular to the wafer.
